(19) United States
(12) Patent Application Publication
(10) Pub. No.: US 2026/0305215 A1
(43) Pub. Date: Oct. 1, 2026

(54) METHOD FOR DICING SEMICONDUCTOR WAFER AND METHOD FOR MANUFACTURING SEMICONDUCTOR DEVICE

(71) Applicant: Resonac Corporation, Minato-ku, Tokyo (JP)

(72) Inventors: Shuntaro HIRATA, Tokyo (JP); Tsuyoshi TAZAWA, Tokyo (JP)

(21) Appl. No.: 19/478,271

(22) PCT Filed: Nov. 22, 2024
(86) PCT No.: PCT/JP2024/041518

§ 371 Date: Oct. 24, 2025

(30) Foreign Application Priority Data
Dec. 4, 2023 (JP) 2023-204833

(51) Int. Cl. H10P 58/00; H10P 54/40; H10P 72/70

(52) U.S. Cl. CPC H10P 58/20; H10P 72/7404; H10P 72/7416; H10P 54/40

(57) ABSTRACT

A method for dicing a semiconductor wafer includes a preparation step of preparing a stack in which an adhesive layer is disposed on a main surface of a semiconductor wafer and a back grind tape is disposed on the adhesive layer, a dicing tape disposing step of disposing a dicing tape on the back grind tape of the stack, and a dicing step of dicing the semiconductor wafer disposed on the back grind tape to singulate the semiconductor wafer into a plurality of semiconductor chips, wherein in the dicing step, the stack is cut from a semiconductor wafer side to a region between the adhesive layer and the dicing tape.

### TECHNICAL FIELD

The present disclosure relates to a method for dicing a semiconductor wafer and a method for manufacturing a semiconductor device.

### BACKGROUND ART

Conventionally, as a technique in such a field, a method described in Patent Literature 1 described below is known. This literature describes face-down dicing as a second embodiment. In face-down dicing, a stack including a semiconductor wafer, an insulating adhesive layer formed on a main surface of the semiconductor wafer, and a back grind tape attached onto the insulating adhesive layer is prepared, a dicing tape is attached to a back grind tape side of the stack, and the semiconductor wafer is diced together with the back grind tape by a dicing blade. As a result, the semiconductor wafer is singulated into a plurality of semiconductor chips. Then, by pushing up the semiconductor chips from the dicing tape side and picking up the semiconductor chips from the dicing tape, multilayer chips in which the insulating adhesive layers are formed on the semiconductor chips are obtained.

### CITATION LIST

### Patent Literature

Patent Literature 1: Japanese Unexamined Patent Publication No. 2006-49482

### SUMMARY OF INVENTION

### Technical Problem

In the method described in Patent Literature 1, since dicing is performed in a state where the insulating adhesive layer is disposed between the semiconductor wafer and the back grind tape, contamination of the insulating adhesive layer due to water wetting or cutting debris is suppressed. In addition, since the back grind tape is disposed between the dicing tape and the semiconductor wafer, cracking of the semiconductor chip when the semiconductor chip is pushed up from the dicing tape side is suppressed. In addition, since the back grind tape can be removed from the semiconductor chip by picking up the semiconductor chip, the process can be shortened.

However, in the method described in Patent Literature 1, the semiconductor wafer is diced together with the back grind tape, and cut extends into the dicing tape. That is, the cutting tip of the dicing blade is positioned within the dicing tape. As a result, the dicing blade entangles the dicing tape, and burrs are likely to be generated.

Therefore, an object of the present disclosure is to provide a method for dicing a semiconductor wafer and a method for manufacturing a semiconductor device capable of suppressing generation of burrs.

### Solution to Problem

[1] A method for dicing a semiconductor wafer according to the present disclosure includes a preparation step of preparing a stack in which an adhesive layer is disposed on a main surface of a semiconductor wafer and a back grind tape is disposed on the adhesive layer, a dicing tape disposing step of disposing a dicing tape on the back grind tape of the stack, and a dicing step of dicing the semiconductor wafer disposed on the back grind tape to singulate the semiconductor wafer into a plurality of semiconductor chips, wherein in the dicing step, the stack is cut from a semiconductor wafer side to a region between the adhesive layer and the dicing tape.

In the method for dicing a semiconductor wafer, the stack in which the adhesive layer is disposed on the main surface of the semiconductor wafer and the back grind tape is disposed on the adhesive layer is prepared, the dicing tape is disposed on the back grind tape of the stack, and the semiconductor wafer disposed on the back grind tape is diced to singulate the semiconductor wafer into the plurality of semiconductor chips. Therefore, contamination of the adhesive layer due to water wetting or cutting debris can be suppressed, cracking of the semiconductor chip when the semiconductor chip is pushed up from the dicing tape side can be suppressed, and the process for releasing the back grind tape from the semiconductor chip can be shortened. Then, when dicing the semiconductor wafer, since the stack is cut from the semiconductor wafer side to a region between the adhesive layer and the dicing tape, the semiconductor wafer can be diced without cutting the dicing tape. As a result, since the dicing tape is not caught by the dicing blade, the generation of burrs can be suppressed. Moreover, since the back grind tape is not completely singulated, the back grind tape can be easily removed when the semiconductor chip is picked up.

[2] The method for dicing a semiconductor wafer according to [1], wherein the back grind tape may include a base material layer and a pressure-sensitive adhesive layer disposed on the base material layer, wherein, in the preparation step, the back grind tape may be disposed on the adhesive layer such that the pressure-sensitive adhesive layer is disposed on an adhesive layer side, and wherein, in the dicing step, the stack may be cut from the semiconductor wafer side to a region between the adhesive layer and the base material layer of the back grind tape. Not only the dicing blade entangles the dicing tape, but also the dicing blade entangles the base material layer of the back grind tape, whereby burrs may be generated. Therefore, in the method for dicing a semiconductor wafer, when the semiconductor wafer is diced, the stack is cut from the semiconductor wafer side to a region between the adhesive layer and the base material layer of the back grind tape, so that the semiconductor wafer can be diced without cutting the base material layer of the back grind tape. As a result, the generation of burrs can be further suppressed, and the back grind tape can be more easily removed when the semiconductor chip is picked up.

[3] The method for dicing a semiconductor wafer according to [1], wherein the back grind tape may include a base material layer and a pressure-sensitive adhesive layer disposed on the base material layer, wherein, in the preparation step, the back grind tape may be disposed on the adhesive layer such that the pressure-sensitive adhesive layer is disposed on an adhesive layer side, and wherein, in the dicing step, the stack may be cut from the semiconductor wafer side to a region between the pressure-sensitive adhesive layer of the back grind tape and the dicing tape. In the method for dicing a semiconductor wafer, when the semiconductor wafer is diced, the stack is cut from the semiconductor wafer side to a region between the pressure-sensitive adhesive layer of the back grind tape and the dicing tape, so that the semiconductor wafer can be diced more reliably.

[4] The method for dicing a semiconductor wafer according to any of [1] to [3], wherein the semiconductor wafer may be provided with a projecting electrode projecting from the main surface. In the method for dicing a semiconductor wafer, since the projecting electrodes are provided on the semiconductor wafer, the semiconductor chip singulated in the dicing step can be easily bonded to the bonding object.

[5] A method for manufacturing a semiconductor device according to the present disclosure, the method including: a pickup step of picking up the semiconductor chip after the method for dicing a semiconductor wafer according to any of [1] to [4]; and a bonding step of bonding the semiconductor chip after the pickup step. In the method for manufacturing a semiconductor device, by performing the pickup step and the bonding step after the dicing step, it is possible to obtain a semiconductor device including the semiconductor chips in which generation of burrs is suppressed.

### Advantageous Effects of Invention

According to the present disclosure, the generation of burrs can be suppressed.

### BRIEF DESCRIPTION OF DRAWINGS

FIG. 1 is a schematic cross-sectional view for describing a method for dicing a semiconductor wafer and a method for manufacturing a semiconductor device according to an embodiment.

FIG. 2 is a schematic cross-sectional view in which a part of the semiconductor wafer illustrated in FIG. 1 is enlarged.

FIG. 3 is a schematic cross-sectional view for describing a method for dicing a semiconductor wafer and a method for manufacturing a semiconductor device according to the embodiment.

FIG. 4 is a schematic cross-sectional view for describing a method for dicing a semiconductor wafer and a method for manufacturing a semiconductor device according to the embodiment.

FIG. 5 is a schematic cross-sectional view for describing a method for dicing a semiconductor wafer and a method for manufacturing a semiconductor device according to the embodiment.

FIG. 6 is a schematic cross-sectional view for describing a method for dicing a semiconductor wafer and a method for manufacturing a semiconductor device according to the embodiment.

FIG. 7 is a schematic cross-sectional view for describing a method for manufacturing a semiconductor device according to the embodiment.

FIG. 8 is a schematic cross-sectional view for describing a method for manufacturing a semiconductor device according to the embodiment.

FIG. 9 is a schematic cross-sectional view for describing a method for dicing a semiconductor wafer and a method for manufacturing a semiconductor device according to a modification example.

FIG. 10 is a schematic cross-sectional view for describing a method for manufacturing a semiconductor device according to the modification example.

FIG. 11(a) is a schematic cross-sectional view illustrating a state before dicing of Comparative Example 1, and FIG. 11(b) is a schematic cross-sectional view illustrating a state after dicing of Comparative Example 1.

FIG. 12(a) is a schematic cross-sectional view illustrating a state before dicing of Comparative Example 2, and FIG. 12(b) is a schematic partially enlarged cross-sectional view illustrating a state after dicing of Comparative Example 2.

FIG. 13(a) is a schematic cross-sectional view illustrating a state before dicing of Example 1, and FIG. 13(b) is a schematic partially enlarged cross-sectional view illustrating a state after dicing of Example 1.

FIG. 14(a) is a schematic cross-sectional view illustrating a state before dicing of Example 2, and FIG. 14(b) is a schematic partially enlarged cross-sectional view illustrating a state after dicing of Example 2.

### DESCRIPTION OF EMBODIMENTS

Hereinafter, the present embodiment is described in detail with reference to the drawings. Hereinafter, the same or corresponding parts are denoted by the same reference numerals, and redundant description will be omitted. In addition, dimensional ratios in the drawings are not limited to the illustrated ratios.

### (Preparation Step)

First, a preparation step of preparing a stack in which an adhesive layer is disposed on a main surface of a semiconductor wafer and a back grind tape is disposed on the adhesive layer is performed.

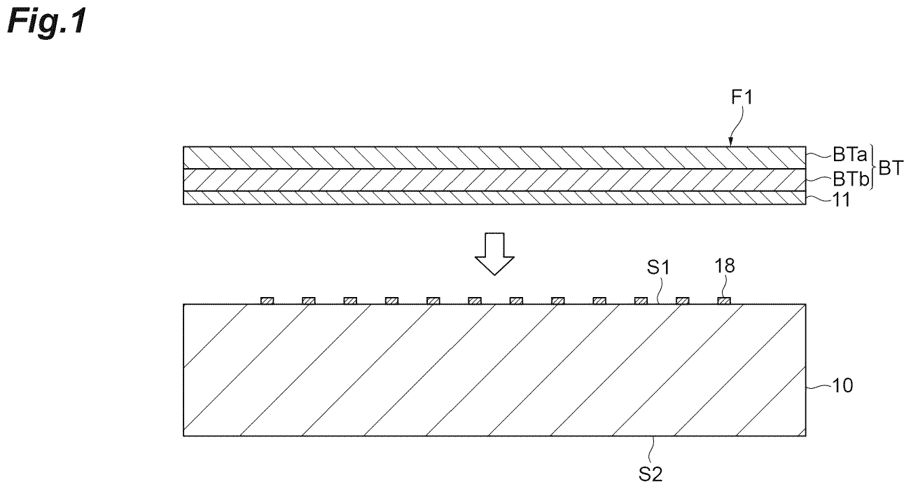

As illustrated in FIG. 1, in the preparation step, a semiconductor wafer 10 and a back grind tape F1 with an adhesive layer are arranged.

The semiconductor wafer 10 has a main surface S1 that is a circuit surface on which a circuit is formed by a semiconductor process, and a back surface S2 that is a surface on the side opposite to the main surface S1. The semiconductor wafer 10 is provided with a plurality of projecting electrodes 18 projecting from the main surface S1 of the semiconductor wafer 10. Note that the thickness of the semiconductor wafer 10 at this time is a state before back grinding, and is, for example, 550 μm to 750 μm.

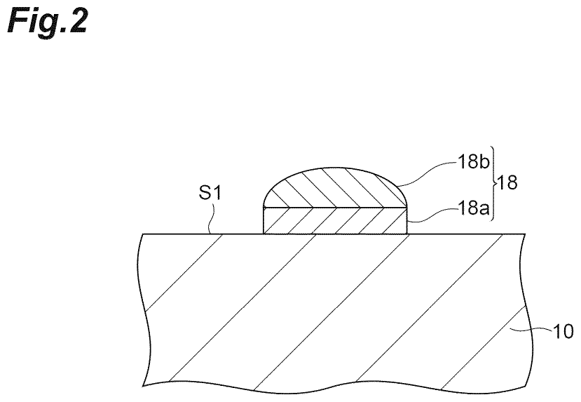

As illustrated in FIG. 2, the projecting electrode 18 is configured to include, for example, a wiring line or bump 18a disposed on the main surface S1 of the semiconductor wafer 10, and a solder 18b disposed on the wiring line or bump 18a.

As illustrated in FIG. 1, the back grind tape F1 with the adhesive layer includes a back grind tape BT and an adhesive layer 11 having a film shape formed on the back grind tape BT. The back grind tape BT includes a base material layer BTa and a pressure-sensitive adhesive layer BTb formed on the base material layer BTa. The adhesive layer 11 is an adhesive layer having insulating properties (insulating adhesive layer), and may be generally referred to as an “NCF (Non-Conductive Film)” or the like. The adhesive layer 11 is attached onto the pressure-sensitive adhesive layer BTb of the back grind tape BT. The back grind tape F1 with the adhesive layer may include a release tape (not illustrated) attached to a surface of the adhesive layer 11 on the side opposite to the back grind tape BT.

Then, the back grind tape F1 with the adhesive layer is attached to the main surface S1 of the semiconductor wafer 10 with the adhesive layer 11 side facing the main surface S1. That is, the adhesive layer 11 and the back grind tape BT are disposed on the main surface S1 of the semiconductor wafer 10. The back grind tape F1 with the adhesive layer can be attached to the semiconductor wafer 10 using, for example, a laminate roll. Note that when the back grind tape F1 with the adhesive layer includes the above-described release tape, the release tape is removed, and the back grind tape F1 with the adhesive layer is attached to the main surface S1 of the semiconductor wafer 10.

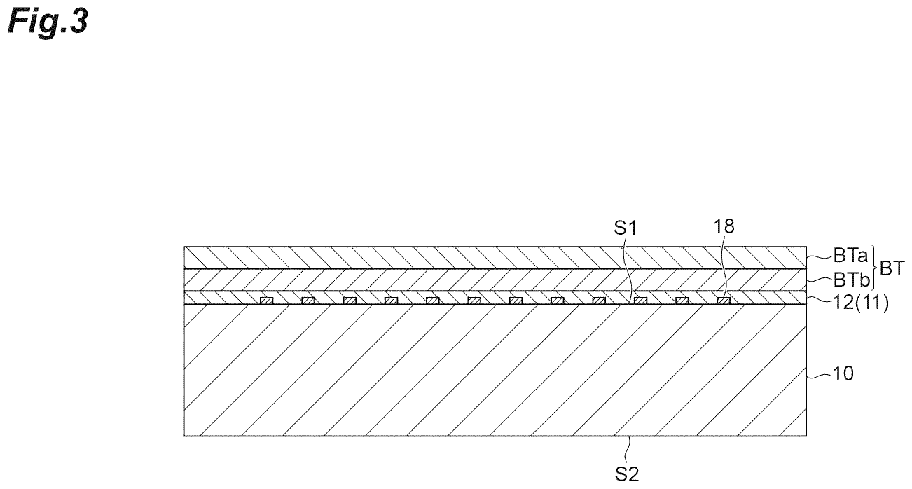

At this time, when the base material layer BTa of the back grind tape BT is pressurized with a predetermined pressure, the adhesive layer 11 is provided so as to fill the spaces between the projecting electrodes 18. As a result, as illustrated in FIG. 3, an adhesive layer 12 in which the projecting electrodes 18 are embedded is formed on the main surface S1. Similarly to the adhesive layer 11, the adhesive layer 12 is an adhesive layer having insulating properties (insulating adhesive layer).

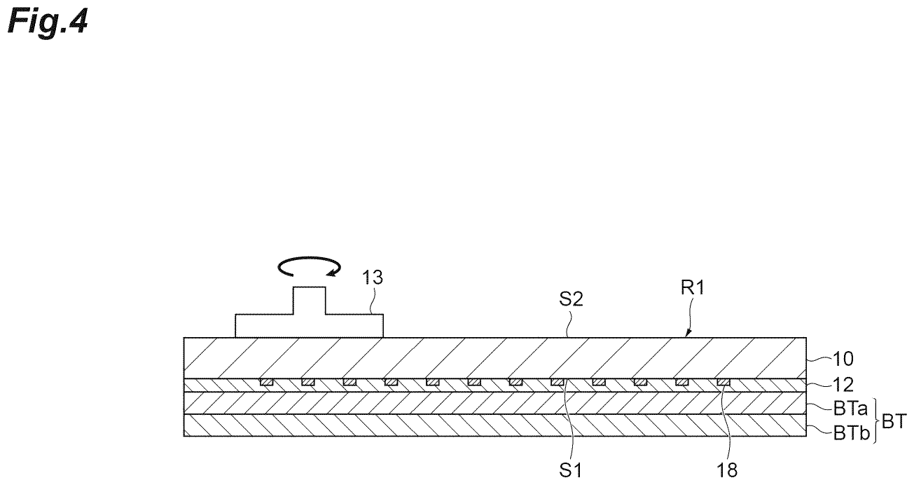

Subsequently, as illustrated in FIG. 4, while the pressure is applied to the back grind tape BT, the semiconductor wafer 10 is ground from the back surface S2 side by a back grinding device (back grinder) 13 to reduce the thickness of the semiconductor wafer 10. At this time, the semiconductor wafer 10 is ground so that the thickness of the semiconductor wafer 10 is, for example, approximately 50 μm to 550 μm. Here, since the back grind tape BT is disposed on the main surface S1 side of the semiconductor wafer 10, the pressure can be uniformly applied. As a result, the back surface S2 of the semiconductor wafer 10 can be planarized by grinding. In addition, the back grind tape BT can suppress damage to the semiconductor wafer 10 during back grinding. As a result, a stack R1 including the thinned semiconductor wafer 10, the adhesive layer 12 disposed on the main surface S1 of the semiconductor wafer 10, and the back grind tape BT disposed on the surface of the adhesive layer 12 on the side opposite to the semiconductor wafer 10 is obtained.

### (Dicing Tape Disposing Step)

Next, a dicing tape disposing step of disposing the dicing tape on the back grind tape of the stack is performed.

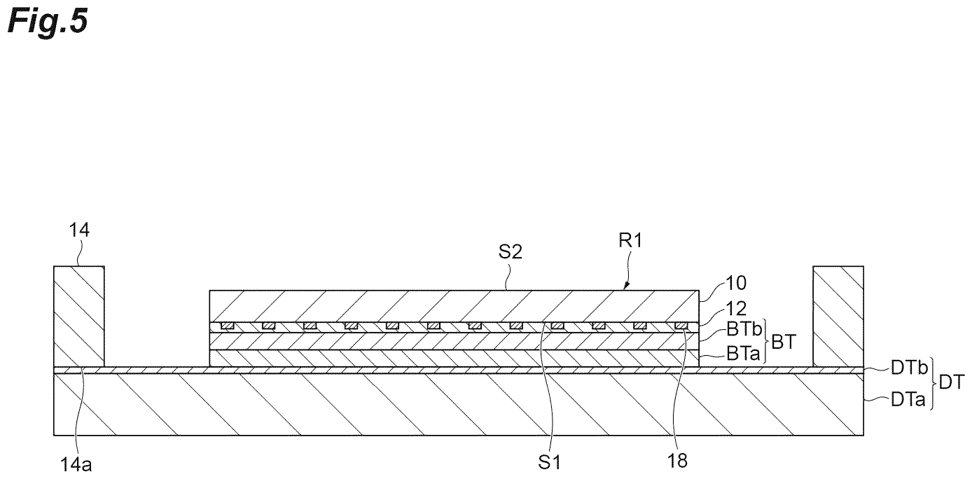

As illustrated in FIG. 5, in the dicing tape disposing step, a dicing tape DT is attached to the surface of the stack R1 on the back grind tape BT side and a lower edge 14a of a dicing frame 14 in a state where the adhesive layer 12 and the back grind tape BT are disposed on the main surface S1 side of the semiconductor wafer 10. The dicing tape DT includes a base material layer DTa and a pressure-sensitive adhesive layer DTb disposed on the base material layer DTa. Then, the pressure-sensitive adhesive layer DTb of the dicing tape DT is attached to the surface of the base material layer BTa on the side opposite to the pressure-sensitive adhesive layer BTb and the lower edge 14a of the dicing frame 14. The dicing frame 14 is an annular metal member and is used as a fixing jig for the semiconductor wafer 10 at the time of dicing the semiconductor wafer 10. The dicing frame 14 has an inner diameter larger than the outer shape of the semiconductor wafer 10, and is disposed on the dicing tape DT so as to surround the semiconductor wafer 10.

### (Dicing Step)

Next, a dicing step of singulating the semiconductor wafer disposed on the back grind tape into a plurality of semiconductor chips is performed.

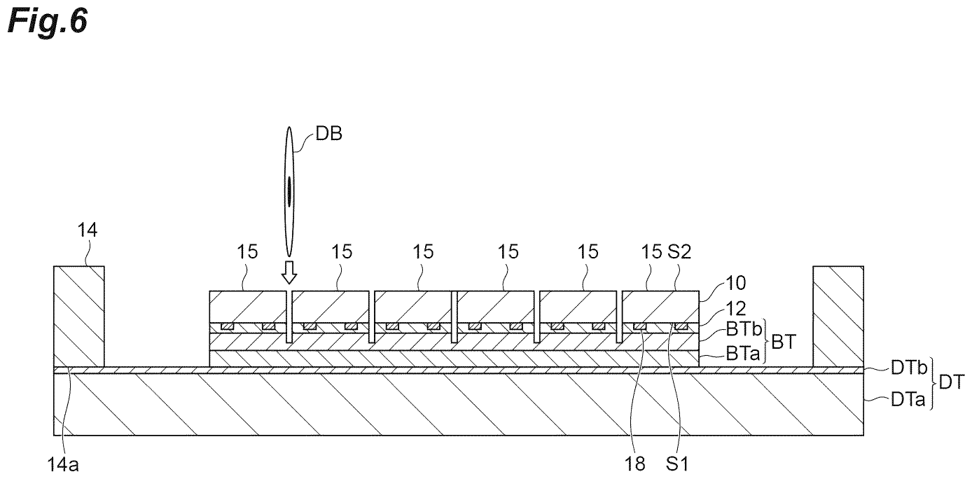

As illustrated in FIG. 6, in the dicing step, with the back surface S2 of the semiconductor wafer 10 facing upward, the semiconductor wafer 10 disposed on the back grind tape BT is diced from the back surface S2 side (so-called face-down dicing) by a dicing blade DB so as to be singulated into a plurality of semiconductor chips 15. At this time, the semiconductor wafer 10 is diced such that the size of the semiconductor chip 15 is, for example, approximately 0.5 mm×0.5 mm.

Then, in the dicing of the semiconductor wafer 10, the stack R1 is cut from the semiconductor wafer 10 side to a region between the adhesive layer 12 and the dicing tape DT. That is, the cutting tip of the dicing blade DB cut into the stack R1 is positioned in a region between the adhesive layer 12 and the dicing tape DT, that is, in the back grind tape BT so that the dicing blade DB does not reach the dicing tape DT. In the present embodiment, the stack R1 is cut from the semiconductor wafer 10 side to a region between the adhesive layer 12 and the base material layer BTa of the back grind tape BT. That is, the cutting tip of the dicing blade DB cut into the stack R1 is positioned in a region between the adhesive layer 12 and the base material layer BTa of the back grind tape BT, that is, in the pressure-sensitive adhesive layer BTb of the back grind tape BT so that the dicing blade DB does not reach the base material layer BTa of the dicing tape DT. As a result, the semiconductor wafer 10 and the adhesive layer 12 are singulated. Note that, in the dicing step, since the dicing blade DB does not reach the dicing tape DT, the back grind tape BT is not completely singulated.

### (Pickup Step)

Next, a pickup step of picking up the semiconductor chip is performed.

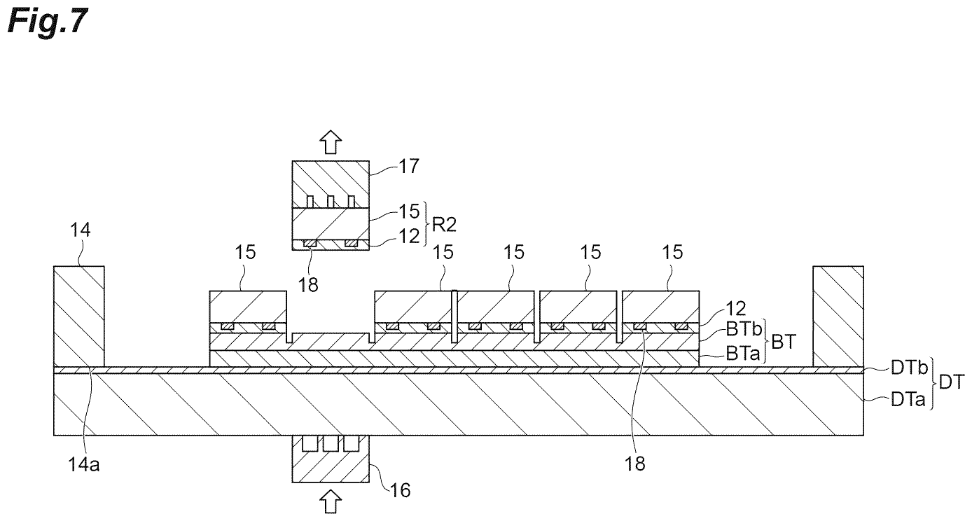

As illustrated in FIG. 7, in the pickup step, the adhesive layer 12 singulated in the dicing step is removed from the back grind tape BT. At this time, when the pressure-sensitive adhesive layer BTb of the back grind tape BT has radiation curability, the adhesive force of the pressure-sensitive adhesive layer BTb can be reduced by irradiation with radiation (for example, ultraviolet rays) prior to releasing.

Subsequently, although not described in detail, after the adhesive force of the pressure-sensitive adhesive layer BTb of the back grind tape BT is reduced by irradiation with ultraviolet rays or the like, the semiconductor chip 15 is pushed up by a push-up jig 16 from below the dicing tape DT, and the semiconductor chip 15 is picked up by a pickup tool 17. As a result, a multilayer chip R2 in which the singulated adhesive layer 12 is attached to the main surface S1 of the semiconductor chip 15 is obtained.

### (Bonding Step)

Next, a bonding step of bonding the semiconductor chip is performed.

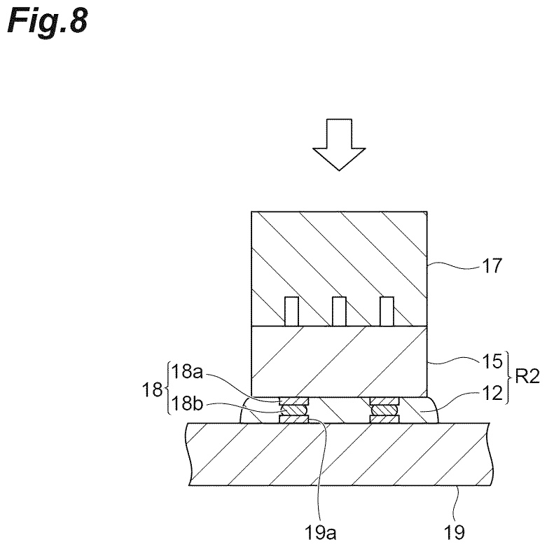

As illustrated in FIG. 8, in the bonding step, the multilayer chip R2 picked up in the pickup step is mounted on a bonding object 19 such as a mounting substrate. Here, for example, the multilayer chip R2 is heated to be crimped to the bonding object 19 to connect the projecting electrodes 18 (solders 18b) of the semiconductor chip 15 and electrodes 19a of the bonding object 19. Then, the projecting electrodes 18 of the semiconductor chip 15 and the electrodes 19a of the bonding object 19 are electrically connected by metal joining. In addition, the projecting electrodes 18 of the semiconductor chip 15 and the electrodes 19a of the bonding object 19 are sealed by the adhesive layer 12, thereby being shielded from the external environment. As a result, a semiconductor device including the semiconductor chip 15 is obtained.

As described above, in the method for dicing a semiconductor wafer and the method for manufacturing a semiconductor device according to the present embodiment, the stack R1 in which the adhesive layer 12 is disposed on the main surface S1 of the semiconductor wafer 10 and the back grind tape BT is disposed on the adhesive layer 12 is prepared, the dicing tape DT is disposed on the back grind tape BT of the stack R1, and the semiconductor wafer 10 disposed on the back grind tape BT is diced to singulate the semiconductor wafer 10 into the plurality of semiconductor chips 15. Therefore, contamination of the adhesive layer 12 due to water wetting or cutting debris can be suppressed, cracking of the semiconductor chip 15 when the semiconductor chip 15 is pushed up from the dicing tape DT side can be suppressed, and the process for releasing the back grind tape BT from the semiconductor chip 15 can be shortened. Then, when dicing the semiconductor wafer 10, since the stack R1 is cut from the semiconductor wafer 10 side to a region between the adhesive layer 12 and the dicing tape DT, the semiconductor wafer 10 can be diced without cutting the dicing tape DT. As a result, since the dicing tape DT is not caught by the dicing blade DB, the generation of burrs can be suppressed. Moreover, since the back grind tape BT is not completely singulated, the back grind tape BT can be easily removed when the semiconductor chip 15 is picked up.

Here, not only the dicing blade DB entangles the dicing tape DT, but also the dicing blade DB entangles the base material layer BTa of the back grind tape BT, whereby burrs may be generated. Therefore, in the method for dicing a semiconductor wafer and the method for manufacturing a semiconductor device, when the semiconductor wafer 10 is diced, the stack R1 is cut from the semiconductor wafer 10 side to a region between the adhesive layer 12 and the base material layer BTa of the back grind tape BT, so that the semiconductor wafer 10 can be diced without cutting the base material layer BTa of the back grind tape BT. As a result, the generation of burrs can be further suppressed, and the back grind tape BT can be more easily removed when the semiconductor chip 15 is picked up.

In addition, in the method for dicing a semiconductor wafer and the method for manufacturing a semiconductor device, since the projecting electrodes 18 are provided on the semiconductor wafer 10, the semiconductor chip 15 singulated in the dicing step can be easily bonded to the bonding object 19.

In addition, in the method for dicing a semiconductor wafer and the method for manufacturing a semiconductor device, by performing the pickup step and the bonding step after the dicing step, it is possible to obtain a semiconductor device including the semiconductor chips 15 in which generation of burrs is suppressed.

Although the method for dicing a semiconductor wafer and the method for manufacturing a semiconductor device according to an embodiment of the present disclosure have been described above, the present disclosure is not limited to the above-described embodiment, and can be appropriately changed without departing from the gist of the present disclosure.

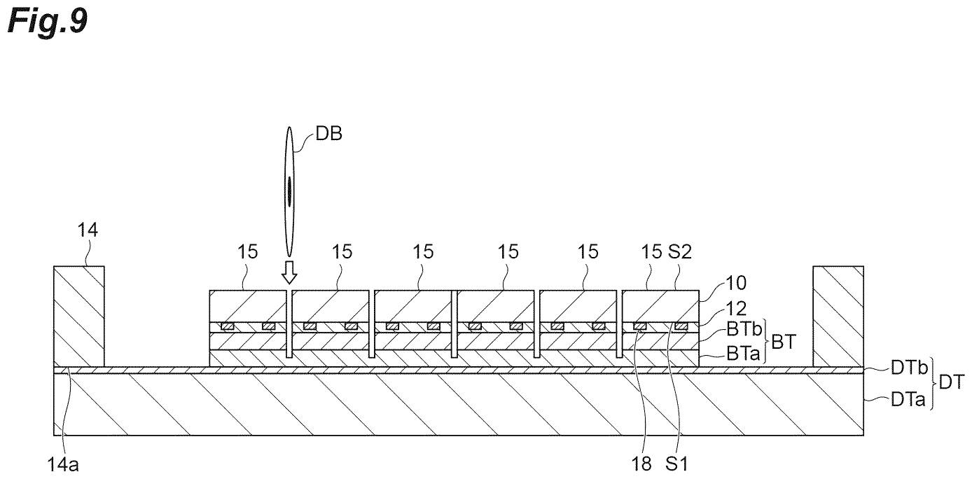

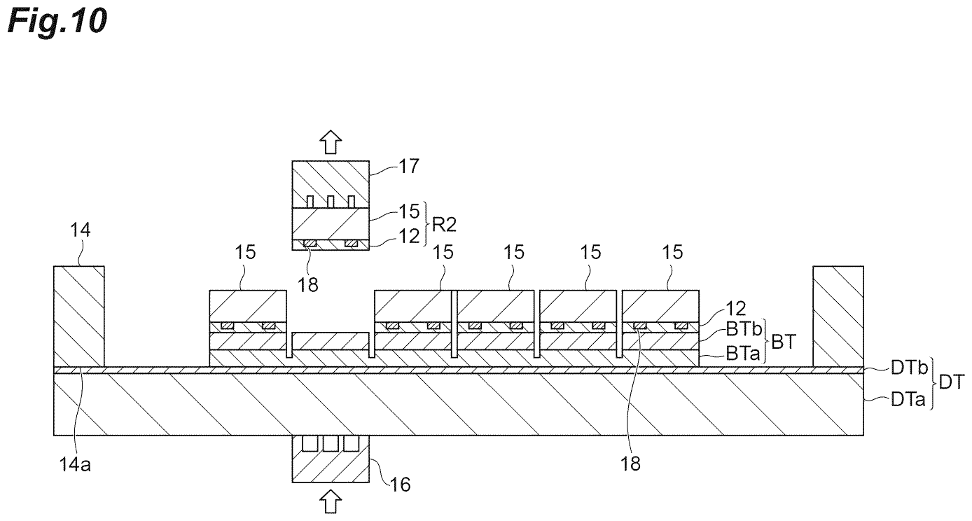

For example, the cutting tip in the stack R1 in the dicing step may be at any position as long as it is in a region between the adhesive layer 12 and the dicing tape DT, and for example, as in a modification example illustrated in FIGS. 9 and 10, it may be positioned in a region between the pressure-sensitive adhesive layer BTb of the back grind tape BT and the dicing tape DT.

As illustrated in FIG. 9, in the dicing step of the modification example, the stack R1 is cut from the semiconductor wafer 10 side to a region between the pressure-sensitive adhesive layer BTb of the back grind tape BT and the dicing tape DT. That is, in the dicing of the semiconductor wafer 10, the cutting tip of the dicing blade DB cut into the stack R1 is positioned in a region between the pressure-sensitive adhesive layer BTb of the back grind tape BT and the dicing tape DT, that is, in the base material layer BTa of the back grind tape BT so that the dicing blade DB does not reach the dicing tape DT. As a result, the semiconductor wafer 10 and the adhesive layer 12 are singulated.

As described above, in the method for dicing a semiconductor wafer and the method for manufacturing a semiconductor device of the modification example, when the semiconductor wafer 10 is diced, the stack R1 is cut from the semiconductor wafer 10 side to a region between the pressure-sensitive adhesive layer BTb of the back grind tape BT and the dicing tape DT, so that the semiconductor wafer 10 can be diced more reliably.

### EXAMPLES

Hereinafter, examples according to the present disclosure will be described. However, the present disclosure is not limited to the examples described below.

### <Production of Film-Shaped Adhesive>

### 1. Source Materials

### (a) Epoxy Resin

Polyfunctional solid epoxy resin having triphenol methane skeleton (EP1032H60, manufactured by Mitsubishi Chemical Corporation, weight-average molecular weight: 800 to 2000)
Bisphenol F type liquid epoxy resin (YL983U, manufactured by Mitsubishi Chemical Corporation, molecular weight: approximately 336)
Flexible semi-solid epoxy resin (YX7110B80, manufactured by Mitsubishi Chemical Corporation, weight-average molecular weight: 1000 to 5000)

### (b) Curing Agent

2,4-diamino-6-[2′-methylimidazolyl-(1′)]-ethyl-s-triazine isocyanuric acid adduct (2MAOK-PW, manufactured by Shikoku Chemicals Corporation)

### (c) Polymer Component

Phenoxy resin (FX-293, manufactured by NIPPON STEEL Chemical & Material Co., Ltd., Tg: approximately 160° C., weight-average molecular weight: 40000 to 50000)

### (d) Flux Agent

Glutaric acid (manufactured by Tokyo Chemical Industry Co., Ltd., melting point: approximately 98° C.)

### (e) Filler

Inorganic filler
Silica filler (SE2030, manufactured by ADMATECHS COMPANY LIMITED, average particle diameter: 500 nm)
Epoxysilane surface-treated silica filler (SE2030, manufactured by ADMATECHS COMPANY LIMITED, average particle diameter: approximately 500 nm)
Methacrylic surface-treated nanosilica filler (YA050C, manufactured by ADMATECHS COMPANY LIMITED, average particle diameter: approximately 50 nm)
   Organic filler
Resin filler (EXL-2655, manufactured by Dow Chemical Japan Limited, core-shell type organic fine particles)

### 2. Production of Film-Shaped Adhesive

A resin varnish containing source materials at a ratio (parts by mass) illustrated in Table 1 was applied to a base material film, and the coating film was dried to produce an adhesive having a film shape (thickness: 20 μm).

TABLE 1

| | | Blending |
|---|---|---|
| Source material | | ratio |
| Phenoxy resin | FX-293 | 20 |
| Epoxy resin | EP-1032H60 | 45 |
| | YL983U | 15 |
| | YX7110B80 | 5 |
| Curing agent | 2MAOK-PW | 2 |
| Flux agent | Glutaric acid | 4 |
| Organic filler | EXL2655 | 10 |
| Inorganic filler | SE2030 | 28 |
| | YA050C | 42 |

### <Production of Back Grind Tape>

### 1. Synthesis of Varnish

An acrylic copolymer using 2-ethylhexyl acrylate and methyl methacrylate as main monomers and hydroxyethyl acrylate and acrylic acid as functional group monomers was obtained by a solution polymerization method. The weight-average molecular weight of the synthesized acrylic copolymer was 400000, and the glass transition point was −38° C. A varnish for a pressure-sensitive adhesive was formulated by blending 10 parts by mass of a polyfunctional isocyanate crosslinking agent (manufactured by Nippon Polyurethane Industry Co., Ltd., trade name “Coronate HL”) with 100 parts by mass of the acrylic copolymer.

### 2. Production of Back Grind Tape

The varnish for a pressure-sensitive adhesive was applied onto a polyethylene terephthalate (PET) base material (manufactured by UNITIKA LTD., trade name “EMBLETS25”) having a thickness of 25 μm using an applicator while adjusting a gap such that the thickness of the pressure-sensitive adhesive layer after drying was 30 μm, and dried at 80° C. for 5 minutes. As a result, the back grind tape in which the pressure-sensitive adhesive layer was formed on the base material was obtained.

### <Production of Dicing Tape>

### 1. Synthesis of Acrylic Resin

As monomers constituting a monomer unit, 2-ethylhexyl acrylate (EHA), 2-hydroxyethyl acrylate (HEA), and methyl methacrylate (MMA) were prepared. These monomers were mixed so as to have a copolymerization ratio of EHA/HEA/MMA=79 parts by mass/20 parts by mass/1 part by mass, ethyl acetate was used as a solvent, and 0.08 parts by mass of azobisisobutyronitrile (AIBN) was used as an initiator, and acrylic resin was obtained by solution radical polymerization.

Then, 0.05 parts by mass of hydroquinone monomethyl ether as a polymerization inhibitor was used and 13.8 parts by mass of 2-methacryloyloxyethyl isocyanate (trade name: Karenz MOI, manufactured by Resonac Corporation, molecular weight: 155.2) was reacted with the obtained acrylic resin to obtain an ultraviolet-reactive acrylic resin having a carbon-carbon double bond. The synthesized acrylic resin may be an acrylic resin having a (meth)acryloyl group and a hydroxyl group. The weight-average molecular weight (in terms of standard polystyrene) of the synthesized acrylic resin was measured by GPC. For the GPC measurement, SD-8022/DP-8020/RI-8020 manufactured by Tosoh Corporation were used. As columns, Gelpack GL-A150-S/GL-A160-S manufactured by Resonac Corporation were used. Tetrahydrofuran was used as an eluent. The weight-average molecular weight of the synthesized acrylic resin was 800000. The hydroxyl value and the acid value of the synthesized acrylic resin measured in accordance with the method described in JIS K 0070:1992 were 33.5 mgKOH/g and 6.5 mgKOH/g, respectively.

### 2. Synthesis of Ultraviolet Curable Pressure-Sensitive Adhesive

An ultraviolet curable pressure-sensitive adhesive solution was formulated by blending 100 parts by mass of the synthesized acrylic resin in terms of solid content, 3.0 parts by mass of an α-hydroxyalkylphenone-based photopolymerization initiator (trade name: Omnirad 184, manufactured by IGM Resins B.V.), 0.6 parts by mass of an acylphosphine oxide-based photopolymerization initiator (trade name: Omnirad 819, manufactured by IGM Resins B.V.), and 4.1 parts by mass of a TDI (toluene diisocyanate) polyisocyanate crosslinking agent (trade name: Coronate L-45E, manufactured by Tosoh Corporation) as a crosslinking agent in terms of solid content, diluting the blend with ethyl acetate and stirring the blend.

### 3. Production of Base Material Film

The thickness ratio was adjusted to polypropylene/vinyl acetate polymer/polypropylene=1/8/1 and the thickness was adjusted to 100 μm by an extruder to obtain a base material film.

### 4. Production of Dicing Tape

The ultraviolet curable pressure-sensitive adhesive solution formulated above was applied onto a polyethylene terephthalate film (thickness: 38 μm) having one surface subjected to mold release treatment so that the thickness after drying was 10 μm, and dried at 80° C. for 3 minutes to produce a pressure-sensitive adhesive layer on the polyethylene terephthalate film. Thereafter, a base material film produced above subjected to corona discharge treatment at one surface was attached to the pressure-sensitive adhesive layer. The attached stack was subjected to aging treatment in a thermostatic bath at 23° C. for 96 hours to obtain a dicing tape including the base material film and the pressure-sensitive adhesive layer provided on the base material film.

### Comparative Example 1

An adhesive layer and a back grind tape were laminated on a main surface of a 12″ silicon wafer. The lamination of the adhesive layer and the back grind tape was performed using a vacuum laminator “CV-300” manufactured by Nikko-Materials Co., Ltd. Next, the back surface of the silicon wafer was ground to set the thickness of the silicon wafer to 50 μm. The silicon wafer was ground using a back grinder “DGP8761” manufactured by DISCO Corporation. Next, the silicon wafer laminated with the adhesive layer and the back grind tape was diced into ¼ size. Dicing was performed using a dicing saw “DFD6361” manufactured by DISCO Corporation.

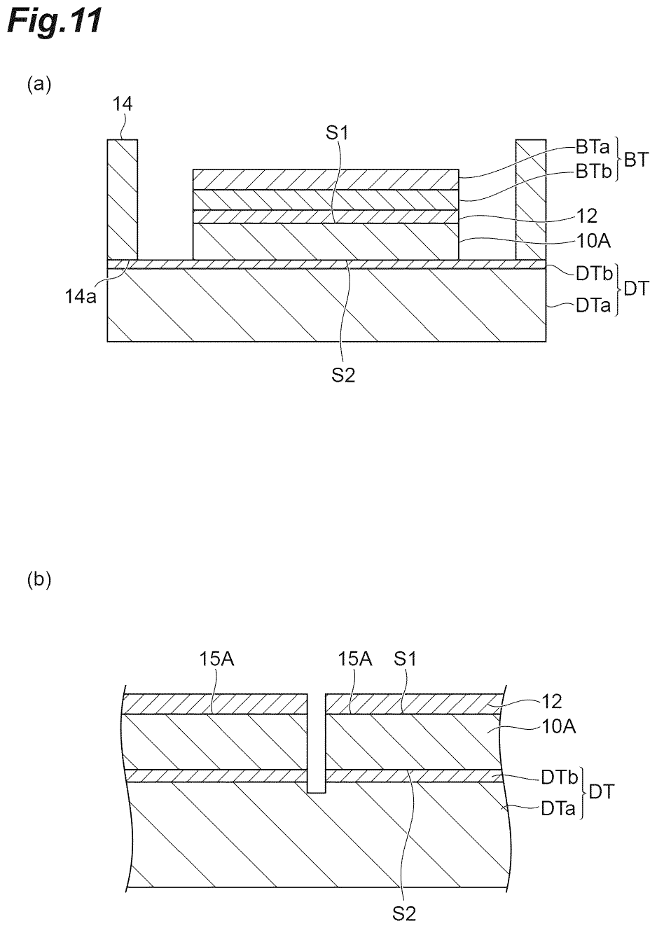

Next, as illustrated in FIG. 11(a), a dicing tape DT was attached to a back surface S2 of a silicon wafer 10A and a lower edge 14a of a dicing frame 14 to have a state where the silicon wafer 10A, an adhesive layer 12, and a back grind tape BT were stacked in this order on the dicing tape DT, and the back grind tape BT was removed from the adhesive layer 12. The dicing tape DT was attached using DM-300-H manufactured by JCM Co., Ltd. under the conditions of 40° C. and 5 mm/s.

Next, as illustrated in FIG. 11(b), the silicon wafer 10A was diced into silicon chips 15A of 5 mm square (5 mm×5 mm). The dicing was performed using a dicing saw “DFD6361” manufactured by DISCO Corporation under the conditions of a rotation speed of the dicing blade: 50000 rpm, a moving speed of the dicing blade: 50 mm/s, a blade cooler: 1 L/min, a shower: 0.8 L/min, and a spray: 0.8 L/min. Then, the cutting depth of the dicing blade was set to a depth position of 20 μm downward (opposite side of the silicon wafer 10A) from the upper surface of a base material layer DTa of the dicing tape DT, and the cutting tip of the dicing blade was positioned in the base material layer DTa of the dicing tape DT.

Then, the surface of the adhesive layer 12 after dicing was observed with a microscope to perform burr evaluation and contamination evaluation. The microscopic observation was performed using a measurement microscope “STM7-DP27” manufactured by Evident Corporation. In the burr evaluation, a case where no burr was observed was evaluated as evaluation A, and a case where a burr was observed was evaluated as evaluation B. In the contamination evaluation, a case where contamination of the adhesive layer 12 due to water wetting or cutting debris was not observed was evaluated as evaluation A, and a case where the adhesive layer 12 due to water wetting or cutting debris was observed was evaluated as evaluation B. The evaluation results are illustrated in Table 2.

Next, the silicon chip 15A was picked up from the dicing tape DT to obtain a multilayer chip in which the singulated adhesive layer 12 was attached to the main surface S1 of the silicon chip 15A. The pickup was performed using DB-800HSD manufactured by FASFORD TECHNOLOGY CO., LTD.

Then, a side surface of the multilayer chip was observed with a microscope to perform burr evaluation. The microscopic observation was performed using a measurement microscope “STM7-DP27” manufactured by Evident Corporation. In the burr evaluation, a case where no burr was observed was evaluated as evaluation A, and a case where a burr was observed was evaluated as evaluation B.

### Comparative Example 2

An adhesive layer and a back grind tape were laminated on a main surface of a 12″ silicon wafer. The lamination of the adhesive layer and the back grind tape was performed using a vacuum laminator “CV-300” manufactured by Nikko-Materials Co., Ltd. Next, the back surface of the silicon wafer was ground to set the thickness of the silicon wafer to 50 μm. The silicon wafer was ground using a back grinder “DGP8761” manufactured by DISCO Corporation. Next, the silicon wafer laminated with the adhesive layer and the back grind tape was diced into ¼ size. Dicing was performed using a dicing saw “DFD6361” manufactured by DISCO Corporation.

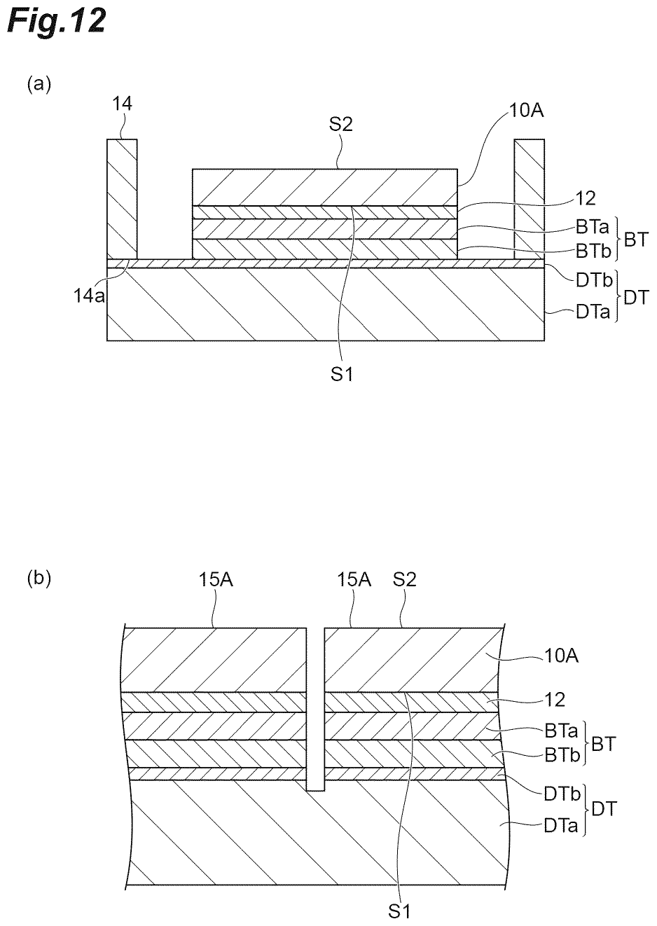

Next, as illustrated in FIG. 12(a), a dicing tape DT was attached to a surface of a back grind tape BT on the side opposite to a silicon wafer 10A and a lower edge 14a of a dicing frame 14 to have a state where the back grind tape BT, an adhesive layer 12, and the silicon wafer 10A were stacked in this order on the dicing tape DT. The dicing tape DT was attached using DM-300-H manufactured by JCM Co., Ltd. under the conditions of 40° C. and 5 mm/s.

Next, as illustrated in FIG. 12(b), the silicon wafer 10A was diced into silicon chips 15A of 5 mm square (5 mm×5 mm). The dicing was performed using a dicing saw “DFD6361” manufactured by DISCO Corporation under the conditions of a rotation speed of the dicing blade: 50000 rpm, a moving speed of the dicing blade: 50 mm/s, a blade cooler: 1 L/min, a shower: 0.8 L/min, and a spray: 0.8 L/min. Then, the cutting depth of the dicing blade was set to a depth position of 20 μm downward (opposite side of the silicon wafer 10A) from the upper surface of a base material layer DTa of the dicing tape DT, and the cutting tip of the dicing blade was positioned in the base material layer DTa of the dicing tape DT.

Then, the surface of the silicon chip 15A after dicing was observed with a microscope to perform burr evaluation and contamination evaluation. The microscopic observation was performed using a measurement microscope “STM7-DP27” manufactured by Evident Corporation. In the burr evaluation, a case where no burr was observed was evaluated as evaluation A, and a case where a burr was observed was evaluated as evaluation B. In the contamination evaluation, a case where contamination of the adhesive layer 12 due to water wetting or cutting debris was not observed was evaluated as evaluation A, and a case where contamination of the adhesive layer 12 due to water wetting or cutting debris was observed was evaluated as evaluation B. The evaluation results are illustrated in Table 2.

Next, the silicon chip 15A was picked up from the dicing tape DT to obtain a multilayer chip in which the singulated adhesive layer 12 was attached to the main surface S1 of the silicon chip 15A. The pickup was performed using DB-800HSD manufactured by FASFORD TECHNOLOGY CO., LTD.

Then, a side surface of the multilayer chip was observed with a microscope to perform burr evaluation. The microscopic observation was performed using a measurement microscope “STM7-DP27” manufactured by Evident Corporation. In the burr evaluation, a case where no burr was observed was evaluated as evaluation A, and a case where a burr was observed was evaluated as evaluation B.

### Example 1

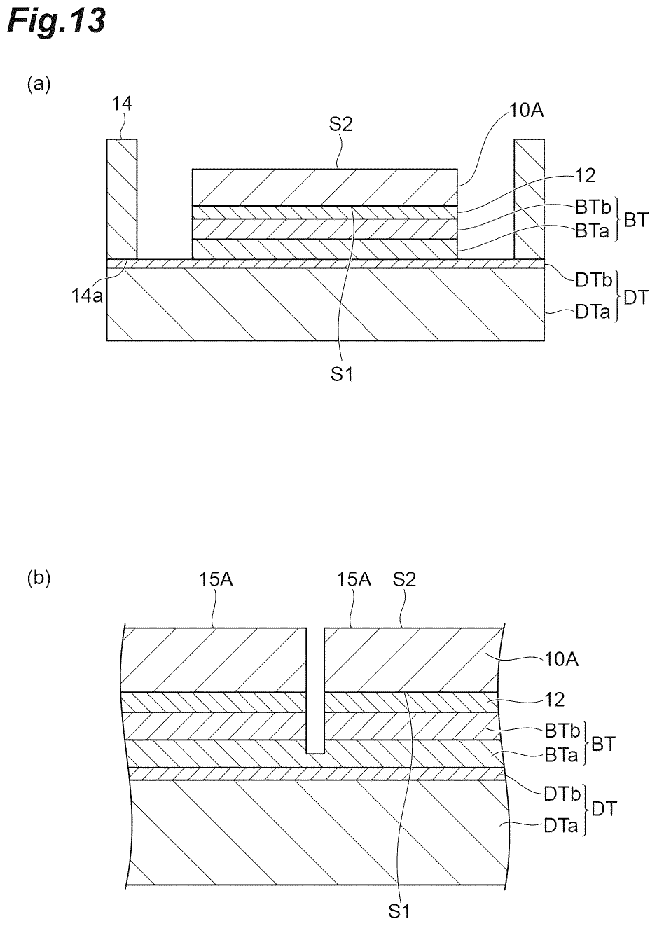

As illustrated in FIGS. 13(a) and 13(b), conditions were the same as in Comparative Example 2 except that the cutting depth of the dicing blade was set to a depth position of 10 μm downward (opposite side of the silicon wafer 10A) from the upper surface of the base material layer BTa of the back grind tape BT, and the cutting tip of the dicing blade was positioned in the base material layer BTa of the back grind tape BT. Then, as in Comparative Example 2, the surface of the silicon chip 15A after dicing was observed with a microscope to perform burr evaluation and contamination evaluation. In addition, a side surface of the multilayer chip was observed with a microscope to perform burr evaluation. The evaluation results are illustrated in Table 2.

### Example 2

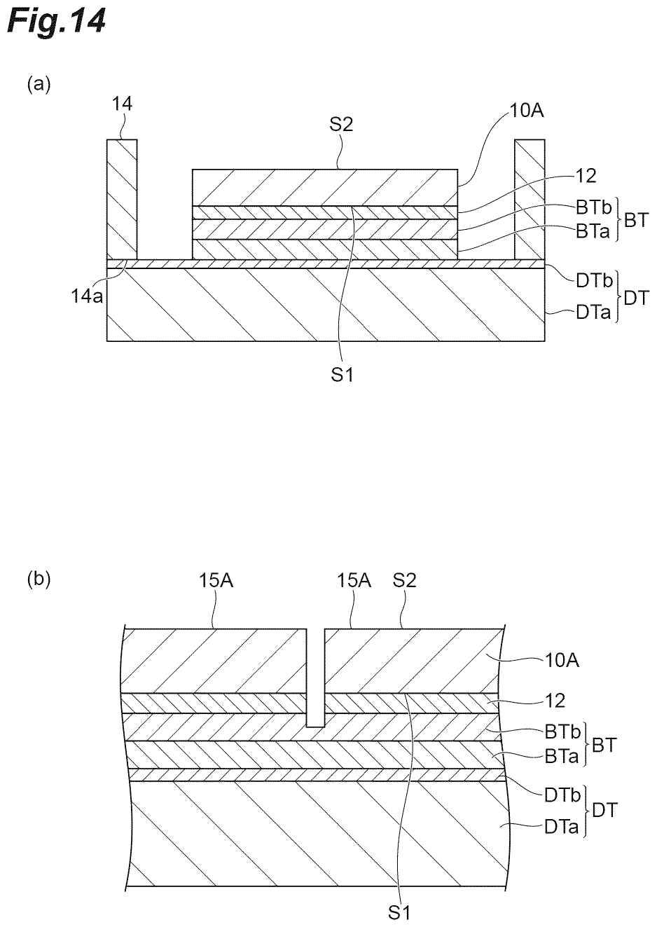

As illustrated in FIGS. 14(a) and 14(b), conditions were the same as in Comparative Example 2 except that the cutting depth of the dicing blade was set to a depth position of 20 μm downward (opposite side of the silicon wafer 10A) from the upper surface of the pressure-sensitive adhesive layer BTb of the back grind tape BT, and the cutting tip of the dicing blade was positioned in the pressure-sensitive adhesive layer BTb of the back grind tape BT. Then, as in Comparative Example 2, the surface of the silicon chip 15A after dicing was observed with a microscope to perform burr evaluation and contamination evaluation. In addition, a side surface of the multilayer chip was observed with a microscope to perform burr evaluation. The evaluation results are illustrated in Table 2.

TABLE 2

| | | Comparative | Comparative | | |
|---|---|---|---|---|---|
| | | Example 1 | Example 2 | Example 1 | Example 2 |
| After dicing | Burr evaluation | B | B | A | A |
| | Contamination | B | A | A | A |
| | evaluation | | | | |
| After pickup | Burr evaluation | B | B | A | A |

### (Evaluation)

As illustrated in Table 2, in Comparative Example 1 in which dicing was performed with the adhesive layer 12 disposed on the uppermost surface, contamination evaluation after dicing was B, but in Comparative Example 2 and Examples 1 and 2 in which dicing was performed with the adhesive layer 12 disposed between the silicon wafer 10A and the back grind tape BT, contamination evaluation after dicing was A.

In addition, in Comparative Examples 1 and 2 in which the dicing tape DT was cut with the dicing blade, both the burr evaluation after dicing and the burr evaluation after pickup were B, whereas in Examples 1 and 2 in which the dicing tape DT was not cut with the dicing blade and the cutting tip of the dicing blade was positioned in the back grind tape BT, both the burr evaluation after dicing and the burr evaluation after pickup were A.

### REFERENCE SIGNS LIST

10 Semiconductor wafer
10A Silicon wafer
11 Adhesive layer
12 Adhesive layer
13 Back grinding device
14 Dicing frame
14a Lower edge
15 Semiconductor chip
15A Silicon chip
16 Push-up jig
17 Pickup tool
18 Projecting electrode
18a Wiring line or bump
18b Solder
19 Bonding object
19a Electrode
BT Back grind tape
BTa Base material layer
BTb Pressure-sensitive adhesive layer
DB Dicing blade
DT Dicing tape
DTa Base material layer
DTb Pressure-sensitive adhesive layer
F1 Back grind tape with adhesive layer
R1 Stack
R2 Multilayer chip
S1 Main surface
S2 Back surface

1. A method for dicing a semiconductor wafer, the method comprising:
preparing a stack in which an adhesive layer is disposed on a main surface of a semiconductor wafer and a back grind tape is disposed on the adhesive layer;
disposing a dicing tape on the back grind tape of the stack; and
dicing the semiconductor wafer disposed on the back grind tape to singulate the semiconductor wafer into a plurality of semiconductor chips,
wherein in the dicing, the stack is cut from a semiconductor wafer side to a region between the adhesive layer and the dicing tape.

2. The method for dicing a semiconductor wafer according to claim 1,
wherein the back grind tape includes a base material layer and a pressure-sensitive adhesive layer disposed on the base material layer,
wherein, in the preparing, the back grind tape is disposed on the adhesive layer such that the pressure-sensitive adhesive layer is disposed on an adhesive layer side, and
wherein, in the dicing, the stack is cut from the semiconductor wafer side to a region between the adhesive layer and the base material layer of the back grind tape.

3. The method for dicing a semiconductor wafer according to claim 1,
wherein the back grind tape includes a base material layer and a pressure-sensitive adhesive layer disposed on the base material layer,
wherein, in the preparing, the back grind tape is disposed on the adhesive layer such that the pressure-sensitive adhesive layer is disposed on an adhesive layer side, and
wherein, in the dicing, the stack is cut from the semiconductor wafer side to a region between the pressure-sensitive adhesive layer of the back grind tape and the dicing tape.

4. The method for dicing a semiconductor wafer according to claim 1,
wherein the semiconductor wafer is provided with a projecting electrode projecting from the main surface.

5. A method for manufacturing a semiconductor device, the method comprising:
picking up the semiconductor chip after the method for dicing a semiconductor wafer according to claim 1; and
bonding the semiconductor chip after the picking up the semiconductor chip.
